(19) United States
(12) Patent Application Publication
(10) Pub. No.: US 2026/0075879 A1
(43) Pub. Date: Mar. 12, 2026

(54) PYRAMID GEOMETRY METAL GATE STRUCTURE

(71) Applicant: Taiwan Semiconductor Manufacturing Co., Ltd., Hsinchu (TW)

(72) Inventors: Hua-Yuan Huang, New Taipei City (TW); Tsu-Hui Su, Taipei City (TW); Ta-Chun Lin, Hsinchu (TW); Jhon Jhy Liaw, Zhudong Township (TW)

(21) Appl. No.: 18/883,950

(22) Filed: Sep. 12, 2024

(51) Int. Cl. H01L 29/423; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 64/018; H10D 30/6736

(57) ABSTRACT

A semiconductor device including a source/drain region, a first nanostructure adjacent the source/drain region, a second nanostructure adjacent the source/drain region, the second nanostructure disposed above the first nanostructure, and a third nanostructure adjacent the source/drain region. The second nanostructure is disposed above the second nanostructure. The semiconductor device also includes a gate structure around the first nanostructure, the second nanostructure, and the third nanostructure. A first portion of the gate structure is disposed between the first nanostructure and the second nanostructure, and a second portion of the gate structure disposed between the second nanostructure and the third nanostructure. The second portion of the gate structure has a smaller length than the first portion of the gate structure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5A, 5B 6A, 6B, 7A, 7B, 7C, 8A, 8B, 9, 10A, 10B, 10C, 11A, 11B, 12A, 12B 12C, 12D, 13A, 13B, 13C, 14A, 14B, 15A, 15B, 16A, 16B, 17A, 17B, 17C, 18A, 18B, 18C, 19A, 19B, 19C, 20A, 20B, 20C, 21A, 21B and 21C are cross-sectional views of intermediate stages in the manufacturing of nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments are described below in a particular context, a die comprising nano-FETs. Various embodiments may be applied, however, to dies comprising other types of transistors (e.g., stacking transistors, or the like) in lieu of or in combination with the nano-FETs.

In some embodiments, the methods and structures described herein provide a gate structure having a pyramid geometry. The methods described herein can employ top-down etch steps to create pyramid geometry metal gate structures, which have a larger metal gate extrusion window for the upper nanostructure metal gate layers than the lower nanostructure metal gate layers. In some embodiments, the pyramid geometry results from changing the width of the spacer. The greater the width of the spacer, the narrower the portion of the gate electrode between the spacers. In some embodiments, by increasing the width of the spacers, the likelihood of the presence of a damage pathway across the spacer may be reduced. However, device performance may be reduced by decreasing the width of the gate electrode, as the resistance of the narrower gate electrode is increased. In the methods and structures described herein, the upper portion of the gate structure may be configured to reduce the likelihood of damage pathways being formed herein, while the lower portion of the gate structure is configured to have a greater width with less resistance. In some embodiments, multi-disposable layers within the nanostructure stack in combination with selective etching can create a tunable inner spacer profile. In some embodiments, the selective etching can control disposable layer profile layer by layer. In some embodiments, the tunable profile for the inner spacer can both enlarge the metal gate extrusion window for forming the gate structure, and can reduce resistive-capacitance (RC) delay.

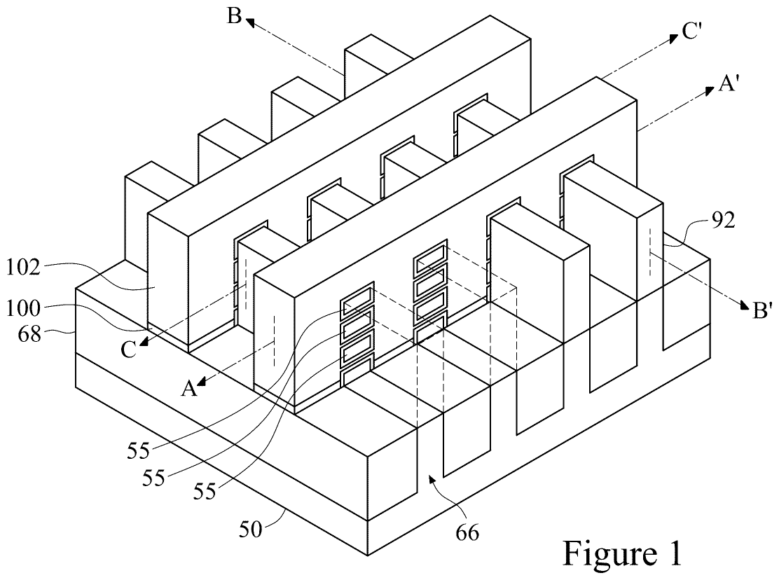

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise a stack of nanostructures 55 (e.g., nanosheets, nanowire, or the like) over fins 66 on a substrate 50 (e.g., a semiconductor substrate), wherein the stack of nanostructures 55 act as channel regions for the nano-FETs. The stack of nanostructures 55 may include p-type nanostructures, n-type nanostructures, or a combination thereof. STI regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the stack of nanostructures 55. Gate electrodes 102 are over the gate dielectric layers 100. Epitaxial source/drain regions 192 are disposed on the fins 66 on opposing sides of the gate dielectric layers 100 and the gate electrodes 102. Source/drain region(s) 192 may refer to a source or a drain, individually or collectively dependent upon the context.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

FIG. 1 further illustrates reference cross-sections that are used in later figures. Cross-section A-A′ is along a longitudinal axis of a gate electrode and in a direction, for example, perpendicular to the direction of current flow between the epitaxial source/drain regions 192 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 192 of the nano-FET. Cross-section C-C′ is parallel to cross-section A-A′ and extends through epitaxial source/drain regions of the nano-FETs. Subsequent figures refer to these reference cross-sections for clarity.

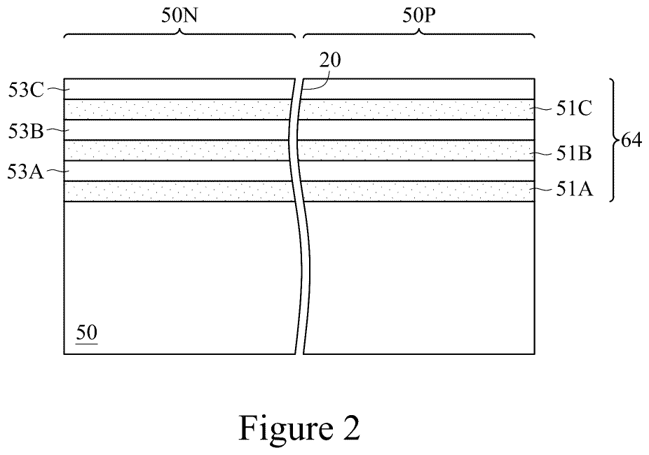

FIGS. 2 through 21C are cross-sectional views of intermediate stages in the manufacturing of nano-FETs, in accordance with some embodiments. FIGS. 2 through 5A, 6A, 7A, 8A, 11A, 12A, 13A, 14A, 15A, 16A, 17A, 18A, 19A, 20A, and 21A illustrate reference cross-section A-A′ illustrated in FIG. 1. FIGS. 6B, 7B, 8B, 9, 10A, 10B, 10C, 11B, 12B, 13B, 14B, 15B, 16B, 17B, 17C, 18B, 19B, 20B, and 21B illustrate reference cross-section B-B′ illustrated in FIG. 1. FIGS. 7C, 12C, 12D, 13C, 18C, 19C, 20C, and 21C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nano-FETs for the n-type region 50N, and the p-type region 50P. In some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or the another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

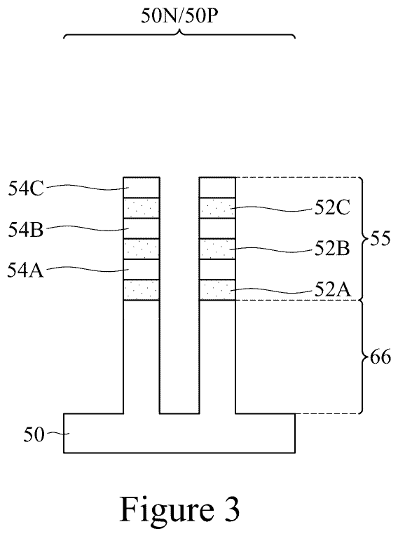

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask 56 may be used to define a pattern of the fins 66 and the nanostructures 55. The hard mask 56 may comprise any suitable insulating material, such as an oxide, a nitride, and oxynitride, and oxycarbonitride, or the like. In some embodiments (not separately illustrated), the hard mask 56 may be a multi-layer structure. The hard mask 56 may be formed over the nanostructures 55 using an acceptable process(es) such as thermal oxidation, physical vapor deposition (PVD), CVD, ALD, combinations thereof, or the like.

The fins 66 and the stack of nanostructures 55 may be patterned by any suitable method. For example, the fins 66 and the stack of nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the stack of nanostructures 55.

Forming the stack of nanostructures 55 by etching the multi-layer stack 64 may further form first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

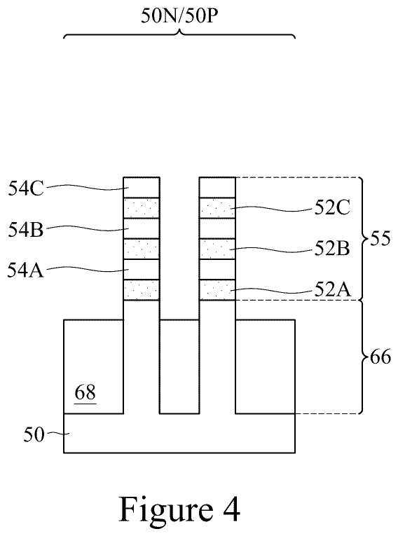

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

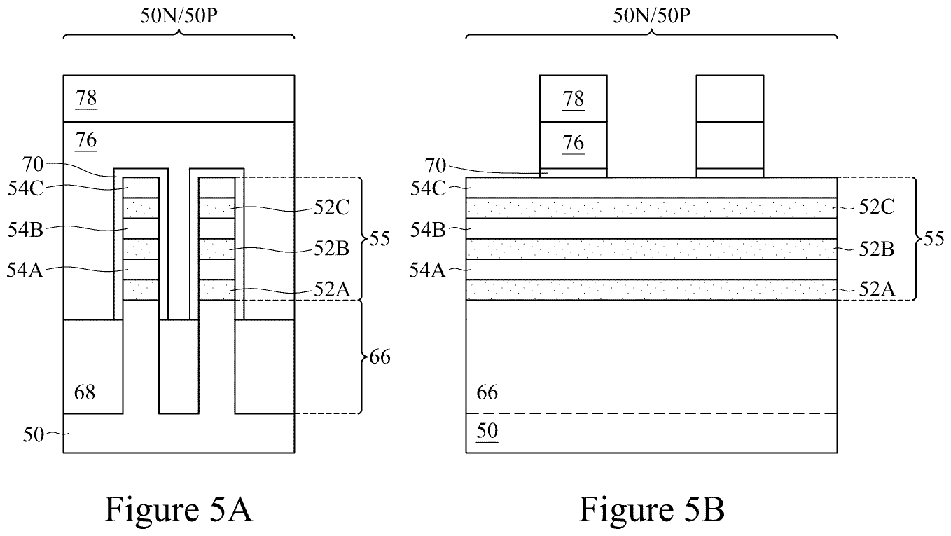

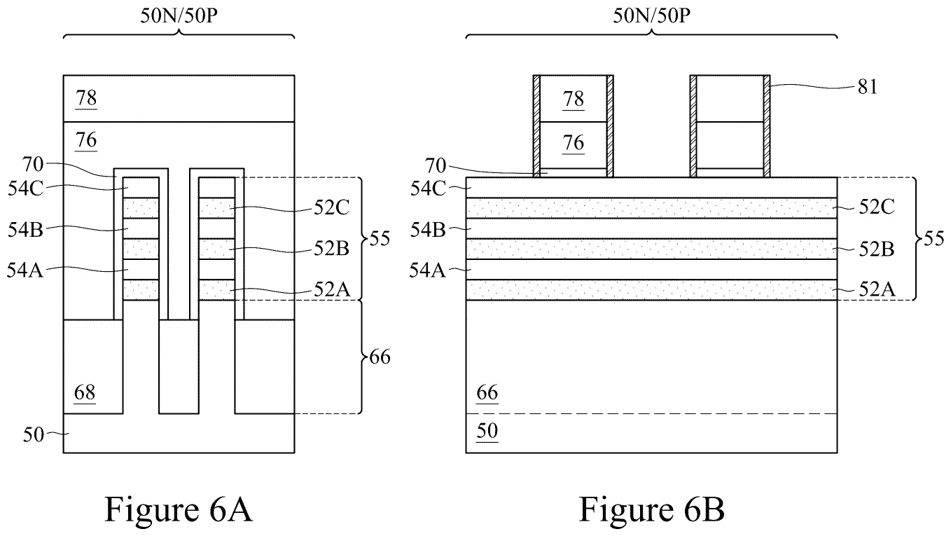

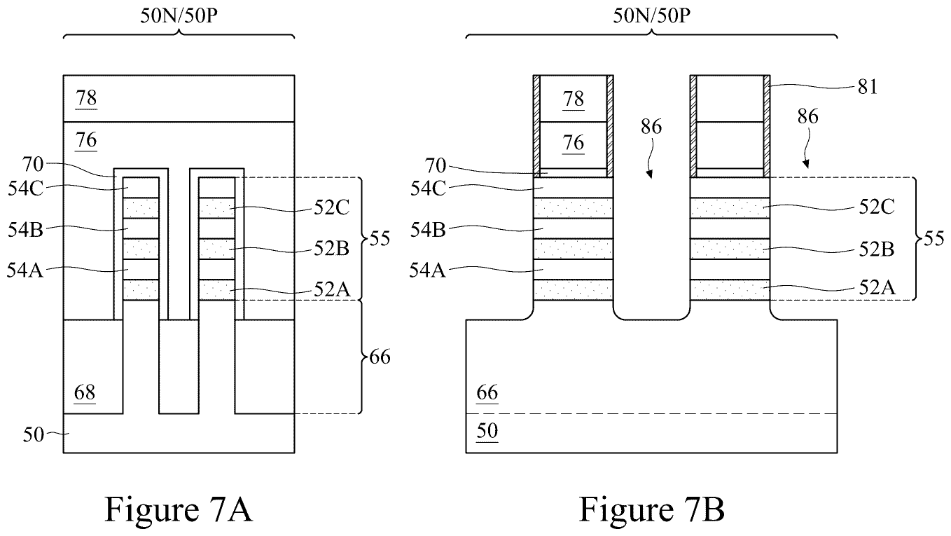

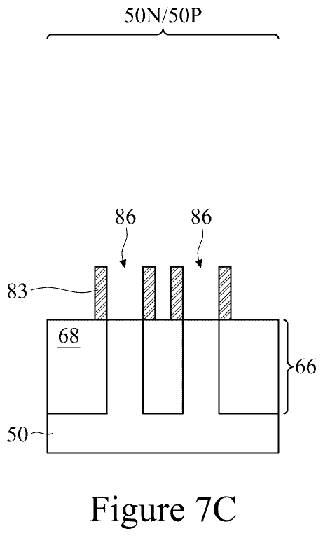

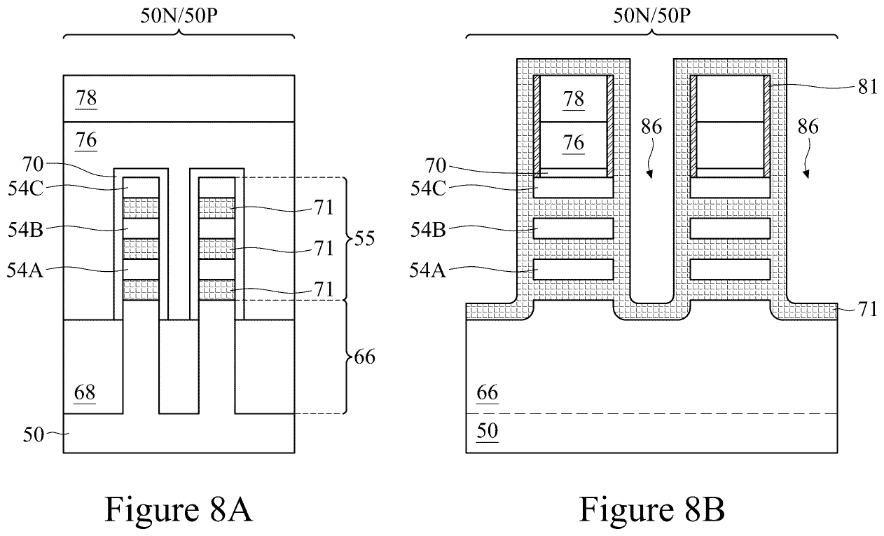

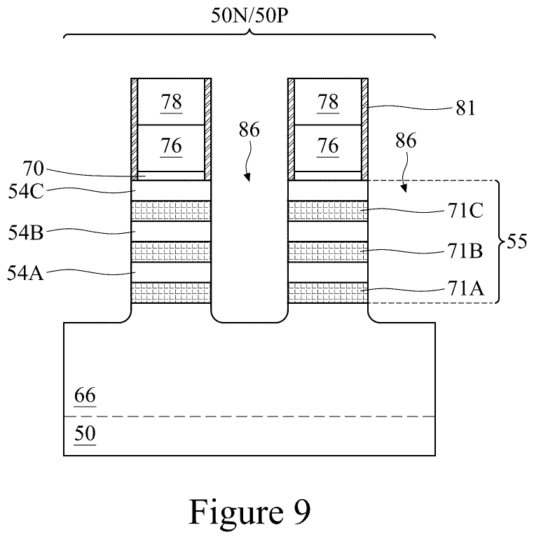

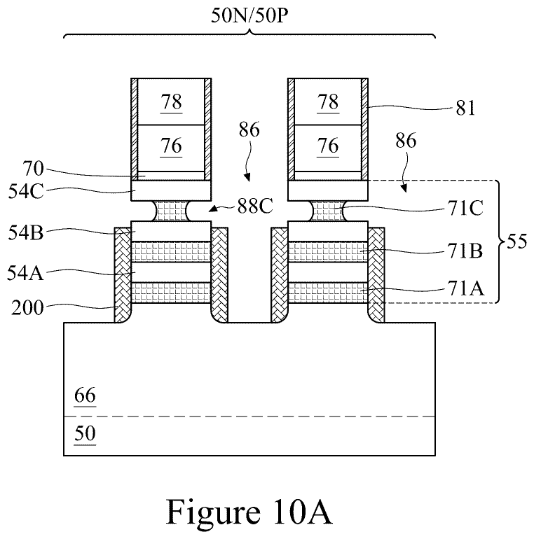

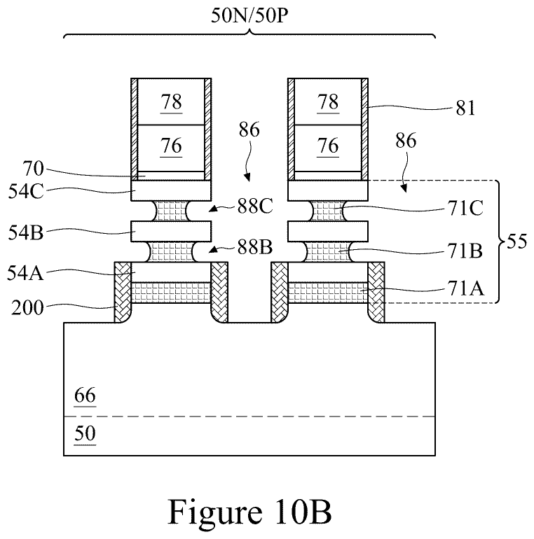

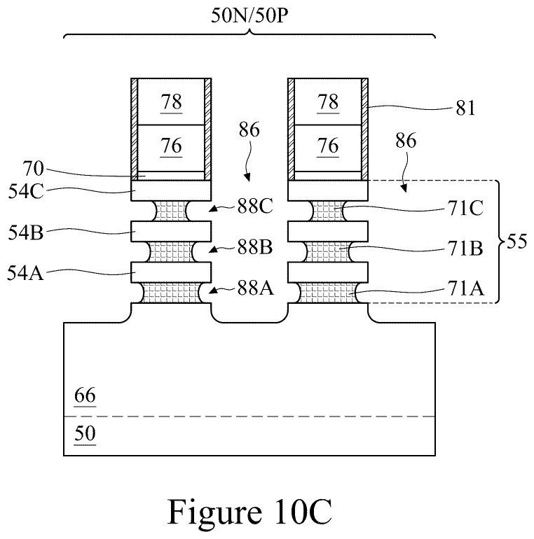

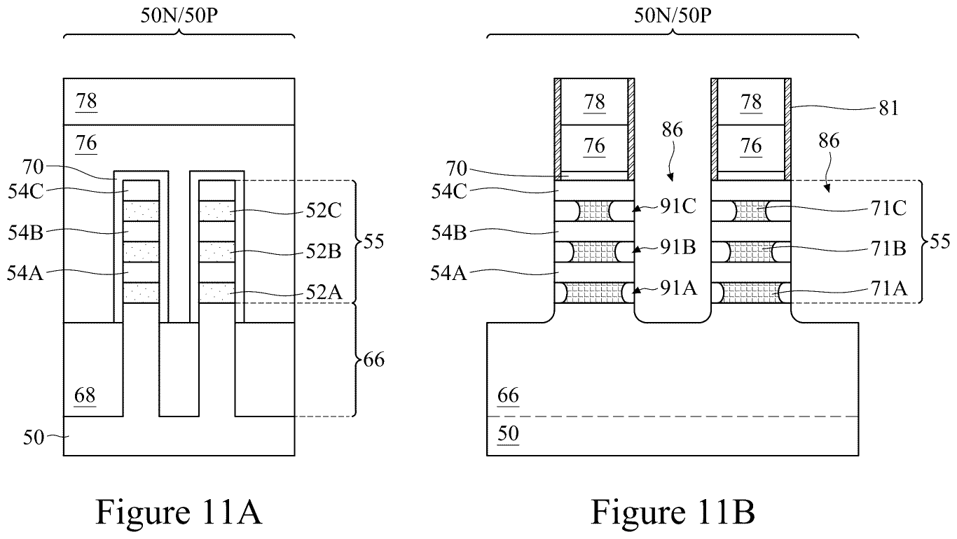

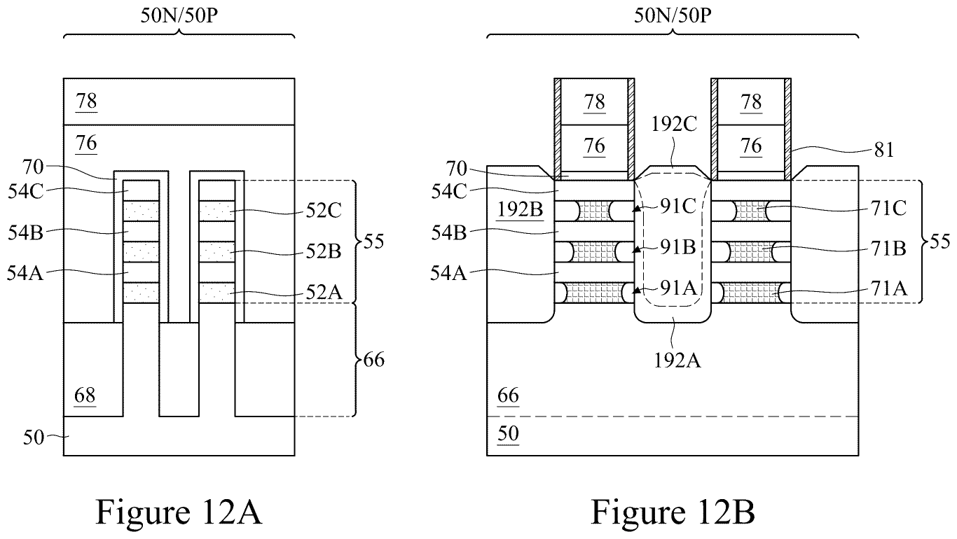

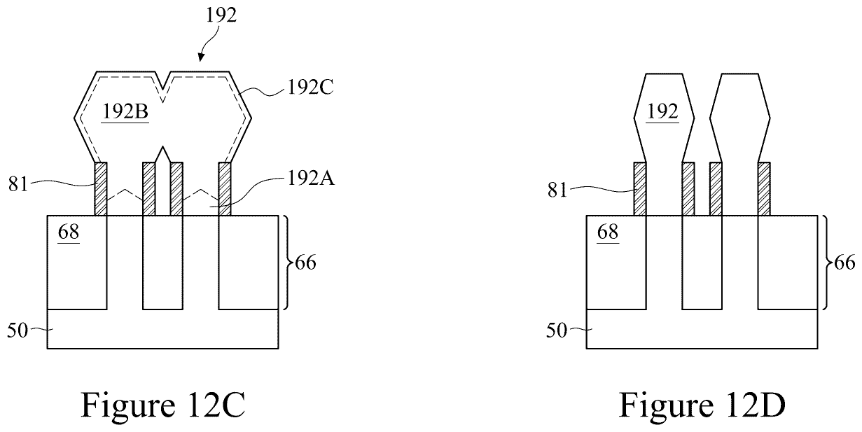

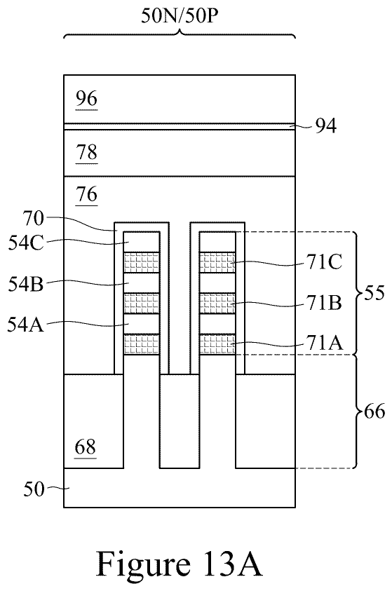

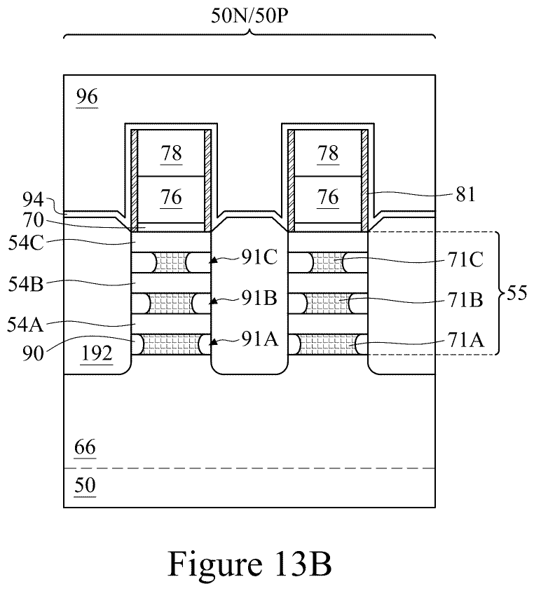

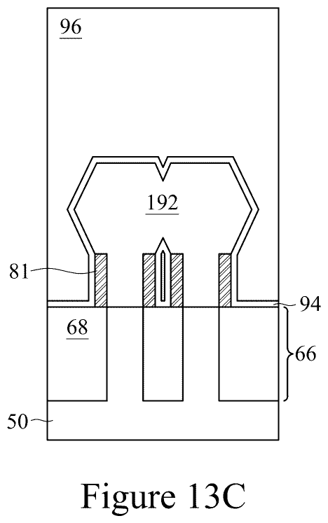

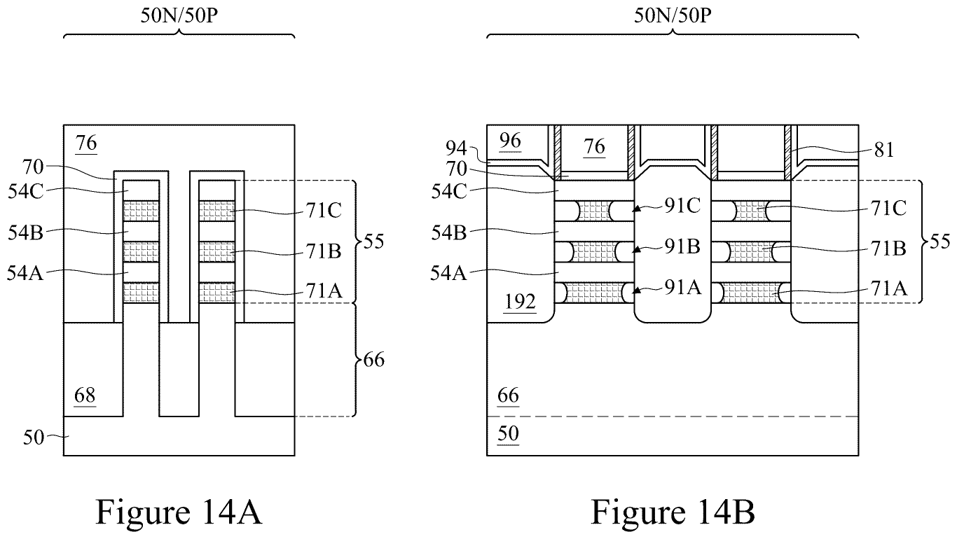

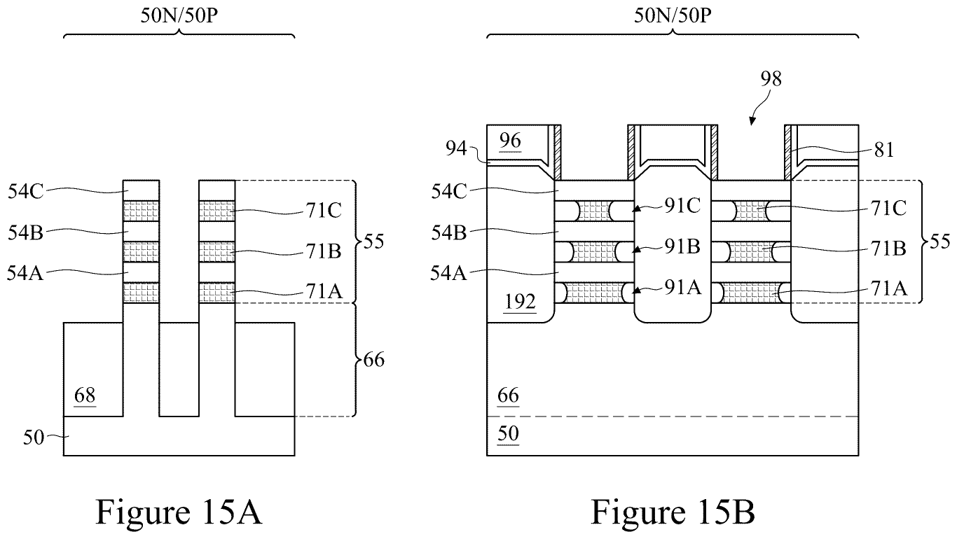

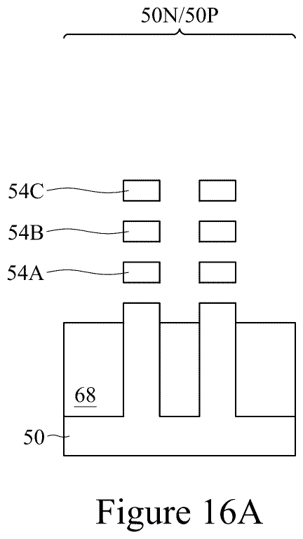

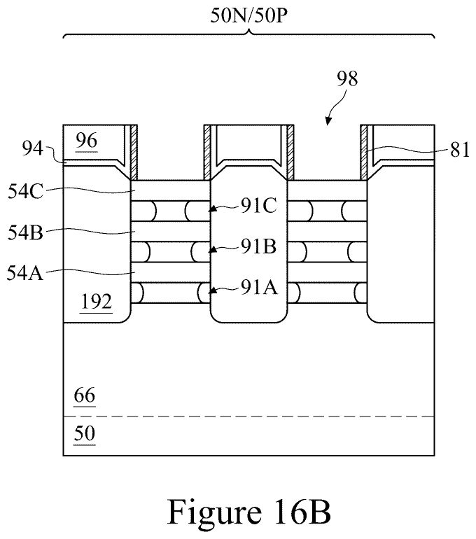

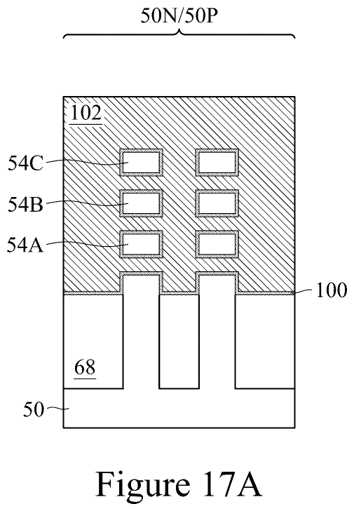

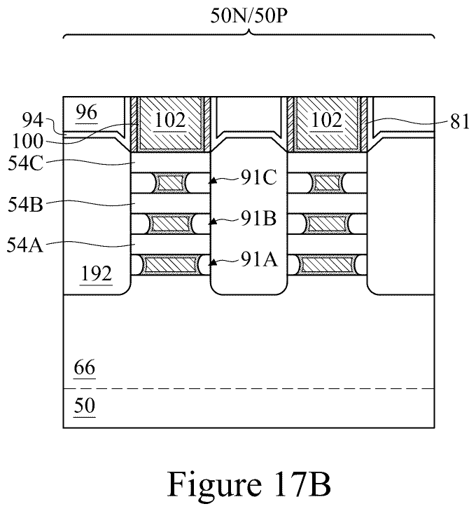

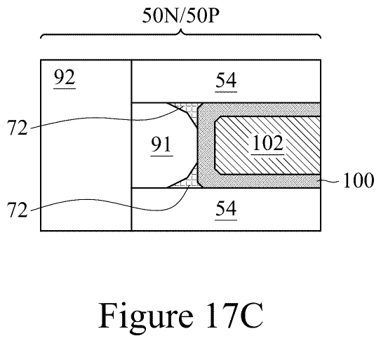

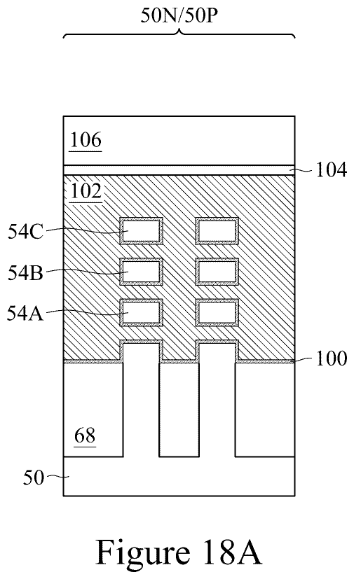

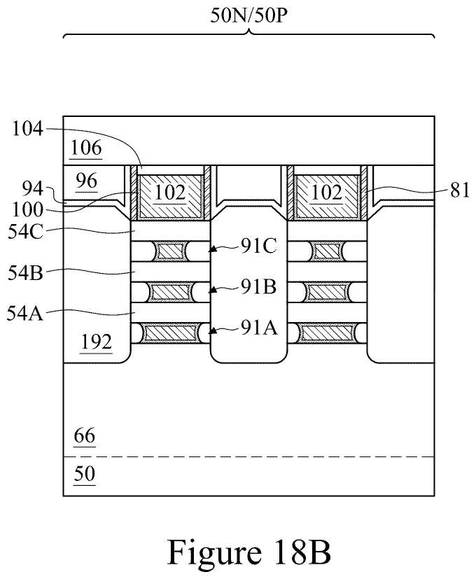

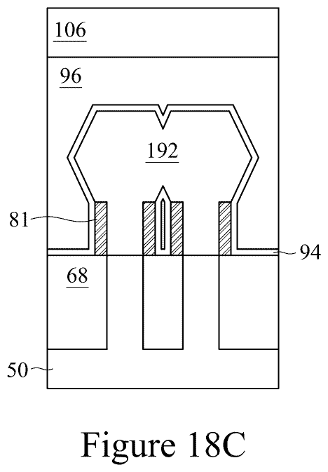

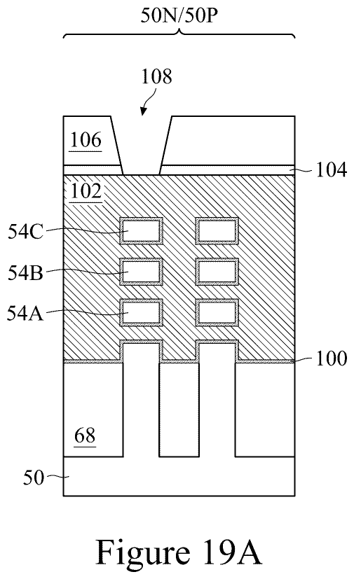

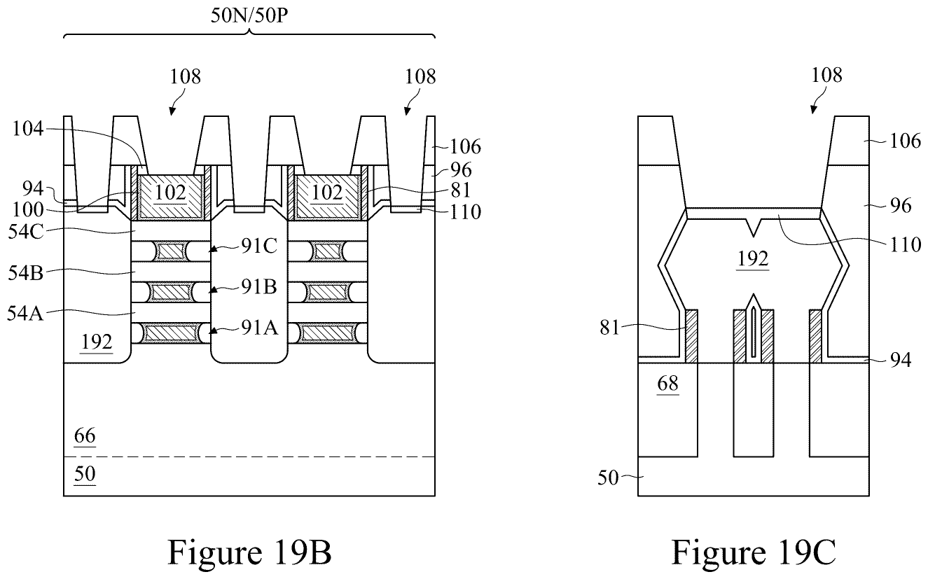

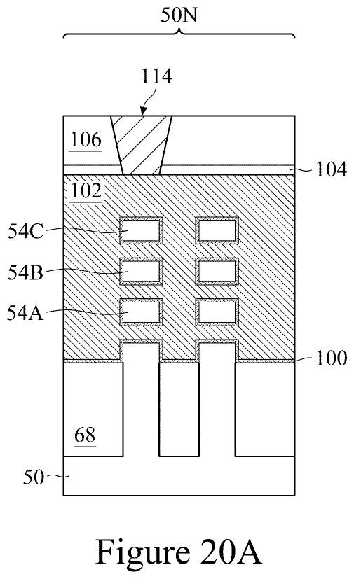

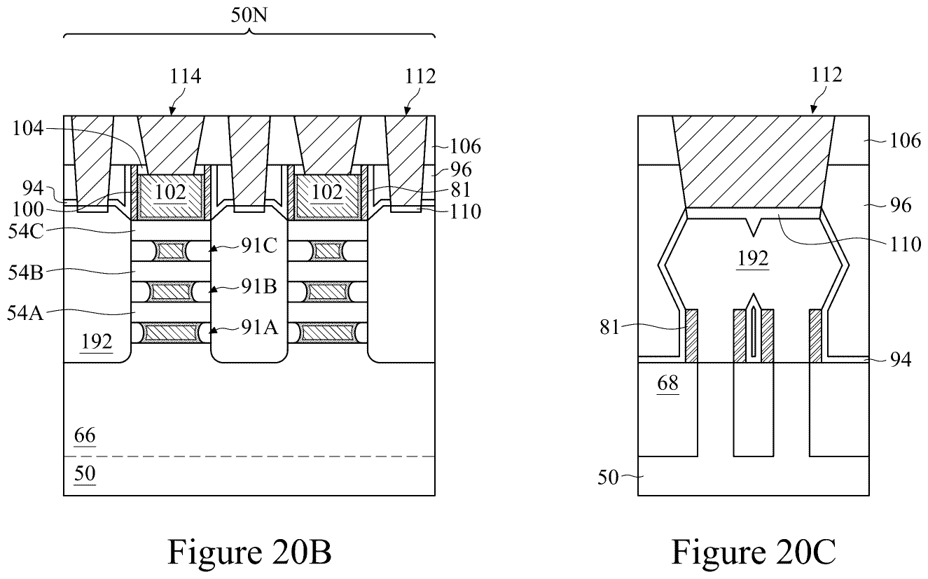

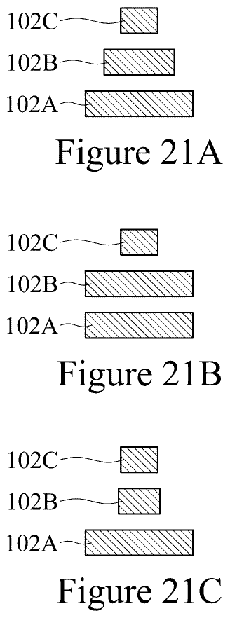

In FIGS. 5A and 5B, dummy gates are formed over and along sidewalls of the stack of nanostructures 55 and the fin 66. To form the dummy gates, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

In FIGS. 6A and 6B, gate spacers 81 are formed over the nanostructures 55 and the STI regions 68, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 81, see FIG. 7C). After etching, the fin spacers 81 and/or the gate spacers 81 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the semiconductor fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the semiconductor fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 10¹⁵ atoms/cm³ to 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 7A-7C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 7C, top surfaces of the STI regions 68 may be level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66, the nanostructures 55, and the substrate 50 using anisotropic etching processes, such as RIE, NBE, or the like. The gate spacers 81, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

In FIGS. 8A-9, the first nanostructures 52 are replaced with a sacrificial material 71A, 71B, 71C (also referred to as disposable oxide interposers (DOI)). Replacing the first nanostructures 52 may include etching away the first nanostructures 52 using a suitable etch process, such as an isotropic etch process, that is performed through the first recesses 86 as illustrated by FIGS. 8A-8B. The etch process may be selective to the material of the first nanostructures 52 and remove the first nanostructures 52 without significantly removing the second nanostructures 54 or the semiconductor fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

Subsequently, a sacrificial material 71 is deposited in the recesses 86 and spaces where the first nanostructures 52 were removed. The sacrificial material 71 may be deposited by a conformal deposition process, such as CVD, ALD, or the like. The sacrificial material 71 may comprise an insulating material such as silicon oxide (e.g., SiO₂), or the like that can be selectively etched from the second nanostructures 54. In FIG. 9, the sacrificial material 71 may then be etched to form the sacrificial material 71A, 71B, 71C. The etching may be isotropic or anisotropic. For example, the sacrificial material layer may be etched by a wet etch process using diluted HF, or the like as an etchant. In some embodiments, the etching is performed until sidewalls of the sacrificial material 71A, 71B, 71C is recessed past sidewalls of the nanostructures.

Replacing the first nanostructures 52 with the sacrificial material 71A, 71B, 71C may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interfaces between the first nanostructures 52 and second nanostructures 54 may result. Such manufacturing defects may degrade the performance of the resulting transistor devices. For example, when germanium diffuses into the second nanostructures 74, germanium residue may remain in channel regions of the resulting transistor devices, which negatively affects the performance of the channel regions. By replacing the first nanostructures 52 with an insulating material prior to the high temperature processes (e.g., source/drain annealing), manufacturing defects can be reduced and device performance can be improved (e.g., increased current drive, reduced capacitance, and improved short channel effect).

In FIGS. 10A-10C, portions of sidewalls of the sacrificial material 71A, 71B, 71C exposed by the first recesses 86 are etched to form sidewall recesses 88A, 88B, 88C in the n-type region 50N, and the p-type region 50P. The sidewall recesses 88A, 88B, 88C may be concave or convex.

Forming the sidewall recesses 88A, 88B, 88C may include a process sequence that allows for at least some of the sacrificial materials 71A, 71B, 71C to be separately etched so that at least some of the recess in the sidewall of each level within a stack of nanostructures 55 can have different dimensions. For example, the sidewall recesses 88C may be larger than the sidewall recesses 88A.

In some embodiments, to provide for selective processing of the layers within the stacks of nanostructures 55, sidewall spacers 200 are formed along sidewalls of the stacks. The sidewall spacers 200 can have a height that exposes at least a portion of the sacrificial materials 71A, 71B, 71C so that they may be etched, while the sidewall spacers 200 protect a remainder of the sacrificial material 71A, 71B, 71C from the etch process, as illustrated in FIG. 10A.

FIG. 10A illustrates forming sidewall spacers 200 that expose the upper (first) sacrificial material 71C in each of the n-type region 50N and the p-type region 50P. The sidewall spacers 200 may be composed of a dielectric material, such as an oxide, nitride or oxynitride material. The dielectric material of the sidewall spacers 200 may be different from the sacrificial materials 71A, 71B, 71C, so that the sacrificial materials 71A, 71B, 71C have a high etching selectivity from the dielectric material of the sidewall spacers 200. In some example, when the sacrificial materials 71A, 71B, 71C are composed of an oxide, such as silicon oxide (SiO₂), the sidewall spacers 200 may be composed of a nitride, such as silicon nitride (Si₃N₄). Other suitable materials may be utilized. For example, the sidewall spacers 200 may be composed of other dielectric materials, such as silicon oxynitride, silicon carbon boride, aluminum oxide, the like, or combinations thereof.

In some embodiments, the sidewall spacers 200 may be formed using a technique such as thermal oxidation or deposition, followed by an etch. For example, the material of the sidewall spacers 200 may be deposited by CVD, ALD, or the like. The material of the sidewall spacers 200 may initially be formed of in layer have a conformal thickness. The layer deposited for the sidewall spacers 200 may then be etched using a suitable etching process, such as an isotropic etching process (e.g., a wet etching process), an anisotropic etching process (e.g., a dry etching process), or the like. In one example, the etch process is an anisotropic etch, such as reactive ion etching. In some examples, the anisotropic nature of the etch process removes the horizontally orientated portions of the layer that provides the sidewall spacers 200. Further, the anisotropic nature of the etch process leaves a remaining portion of the sidewall spacers 200 that is vertically orientated abutting the sidewalls of the stacks of nanostructures 55.

FIG. 10A illustrates that the etch process for defining the geometry of the sidewall spacers 200 may continue to vertically recess the upper surface of the sidewall spacers 200 in order to expose sidewalls surfaces of the first (upper) sacrificial material 71C. FIG. 10A illustrates that the upper surface of the sidewall spacers 200 has been recessed to provide that the height of the sidewall spacers 200 is sufficiently tall to protect the second and third (middle and lower) sacrificial materials 71B, 71A, while leaving the first (upper) sacrificial material 71C exposed. The height of the sidewall spacers 200 may be recessed to an appropriate level by using a timed anisotropic etch.

FIG. 10A also illustrates that after forming the sidewall spacers 200 having a height that is recessed to expose the first (upper) sacrificial material 71C, an etch process may be applied to laterally etch the sidewalls of the first (upper) sacrificial material 71C. The lateral etch process forms first upper recesses 88C in the sidewalls of the first (upper) sacrificial material 71C.

In some embodiments, the sidewalls of the first (upper) sacrificial material 71C may be etched using isotropic etching processes, such as wet etching or the like. Etchants selective for removing the first (upper) sacrificial material 71C are employed, such that the second nanostructures 54C and the substrate 50 remain relatively unetched.

FIG. 10B illustrates recessing the sidewall spacers 200 to expose a second portion of the sacrificial materials 71A, 71B, 71C, e.g., a second (middle) sacrificial material 71B. The height of the sidewall spacers 200 may be recessed using an anisotropic etch process, such as reactive ion etching (RIE). In some embodiments, the height of the sidewall spacers 200 is recessed to expose the middle portions of the layers within the stacks of nanostructures 55. FIG. 10B illustrates that the upper surface of the sidewall spacers 200 has been recessed to provide that the height of the sidewall spacers 200 is sufficiently tall to protect the third (lower) sacrificial material 71A, while leaving the first (upper) sacrificial material 71C and second (middle) sacrificial material 71B exposed. The height of the sidewall spacers 200 may be recessed to an appropriate level by using a timed anisotropic etch.

FIG. 10B further illustrates second laterally etching a second portion of the sacrificial layers 71A, 71B, 71C. For example, with the height of the sidewalls spacers 200 further recessed, the sacrificial materials that are exposed can include the first (upper) sacrificial material 71C and the second (middle) sacrificial material 71B. The second lateral etch is an initial etch applied to the newly exposed sidewalls of the second (middle) sacrificial material 71B. The second lateral etch forms middle first recesses 88B in the sidewalls of the second (middle) sacrificial material 71B. However, during the second lateral etch step, the first (upper) sacrificial material 71C are also exposed, and therefore receive a second dose of etchant to the sidewalls of the first (upper) sacrificial material 71C. This provides that the first (upper) recesses 88C are further extended into the sidewalls of the first (upper) sacrificial material 71C.

In some embodiments, the sidewalls of the first (upper) sacrificial material 71C and second (middle) sacrificial material 71B may be etched using isotropic etching processes, such as wet etching or the like. Etchants selective for removing the first (upper) sacrificial material 71C and second (middle) sacrificial material 71B are employed, such that the second nanostructures 54C and the substrate 50 remain relatively unetched.

In the illustrated embodiment, following the second lateral etch, the depth of the first (upper) recesses 88C into the remaining portions of the first (upper) sacrificial material 71C is greater than the depth of the second (middle) 88B into the remaining portions of the second (middle) sacrificial material 71B. In another embodiment (subsequently described), following the second lateral etch, the depth of the first (upper) recesses 88C into the remaining portions of the first (upper) sacrificial material 71C is equal to the depth of the second (middle) 88B into the remaining portions of the second (middle) sacrificial material 71B.

FIG. 10C illustrates recessing the sidewall spacers 200 to expose a third portion of the sacrificial material, e.g., a third (lower) sacrificial material 71A. The height of the sidewall spacers 200 may be recessed using an anisotropic etch process, such as reactive ion etching (RIE). In some embodiments, the height of the sidewall spacers 200 is recessed to expose the lower portions of the layers within the stacks of nanostructures 55. FIG. 10C illustrates that the sidewall spacers 200 have been entirely removed. In view of the sidewall spacers 200 being removed, the sidewalls of each of the sacrificial materials 71A, 71B, 71C is exposed. The sidewall spacers 200 may not be entirely removed. In some embodiments, a portion of the sidewall spacer 200 may remain.

FIG. 10C further illustrates third laterally etching a third portion of the disposable layers. For example, with the sidewalls spacer 200 removed or recessed, the sacrificial materials exposed include the first (upper) sacrificial material 71C, the second (middle) sacrificial layer 71B, and the third (lower) sacrificial material 71A. The third lateral etch is an initial etch applied to the newly exposed sidewalls of the third (lower) sacrificial material 71A. The third lateral etch forms a lower first recess 88A in the sidewall of the third (lower) sacrificial material 71A. However, during the third lateral etch step, the first (upper) sacrificial material 71C and the second (middle) sacrificial material 71B are also exposed. This provides that the first (upper) sacrificial material 71C is etched with three different etch treatments. The second (middle) sacrificial material 71B is exposed to a second etch process. Each receive additional etching that is applied to the sidewalls of the first (upper) sacrificial material 71C and the second (middle) sacrificial material 71B. This provides that the first (upper) recesses 88C and the second (middle) recesses 88B are further extended into the sidewalls of the first (upper) sacrificial material 71C and the second (middle) sacrificial material 71B.

In some embodiments, the sidewalls of the first (upper) sacrificial material 71C, the second (middle) sacrificial material 71B, and the third (lower) sacrificial material 71A may be etched using isotropic etching processes, such as wet etching or the like. Etchants selective for removing the first (upper) sacrificial material 71C, the second (middle) sacrificial material 71B, and the third (lower) sacrificial material 71A are employed, such that the second nanostructures 54C and the substrate 50 remain relatively unetched.

In the illustrated embodiment, following the third lateral etch, the depth of the first (upper) recesses 88C is greater than the depth that the first (upper) recesses 88C had following the second lateral etch. The depth of the first (upper) recesses 88C is greater than the depth of the second (middle) recesses 88B. Similar to the first (upper) recesses 88C, following the third lateral etch, the depth of the second (middle) recesses 88B is greater than the depth of the second (middle) recesses 88B following the second lateral etch. Following the third lateral etch, the depth of the second (middle) recesses 88B into the remaining portions of the second (middle) sacrificial material 71B is greater than the depth of the third (lower) recesses 88A into the remaining portions of the third (lower) sacrificial material 71A. In another embodiment (subsequently described), following the third lateral etch, the depth of the second (middle) recesses 88B into the remaining portions of the second (middle) sacrificial material 71B is equal to the depth of the third (lower) recesses 88A into the remaining portions of the third (lower) sacrificial material 71A.

It is noted that the example depicted in FIGS. 10A-10C is only one example of the present disclosure, and it is not intended that the disclosure be limited to only this example. For example, the number of disposable layers may be more than or less than the number of disposable layers that are illustrated in the specific example depicted in FIGS. 10A-10C. Further, the number of recess and lateral etching steps for forming the openings in the sidewalls of the disposable layers may be increased and/or decreased.

In FIGS. 11A-11B, inner spacers 91A, 91B, 91C are formed in the recesses 88A, 88B, 88C in the sidewalls of the sacrificial materials 71A, 71B, 71C. The inner spacers 91A, 91B, 91C may be formed depositing an inner spacer layer (not separately illustrated) over the structure illustrated in FIG. 10C, e.g., in the recesses 86 and the recesses 88A, 88B, 88C. The inner spacers 91A, 91B, 91C act as isolation features between subsequently formed source/drain regions and subsequently formed gate structures. As will be discussed in greater detail below, source/drain regions will be formed in the recesses 86, while the remaining portions of the sacrificial materials 71A, 71B, 71C will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 91A, 91B, 91C. The inner spacer layer may be etched by an anisotropic etching process, such as RIE, NBE, or the like.

The inner spacers 91A, 91B, 91C are present between vertically spaced and adjacent second nanostructure layers 54A, 54B, 54C. The first (upper) inner spacer 91C is present proximate to an upper surface of the stack of nanostructures 55 and has a greater width than the second (middle) inner spacer 91B. The third (lower) inner spacer 91A is proximate to a base surface of the stack of nanostructures 55 and has a width that is less than the width of the second (middle) inner spacer 91B.

The formation of the gate structures (including metal gate electrodes) can result in the formation of damage pathways across the inner spacers 91A, 91B, 91C. The damage pathways may be openings and/or metal traces that extend across the inner spacers 91A, 91B, 91C. In some embodiments, metal traces extending through the damage pathways can provide a bridge between the gate electrodes and the source/drain regions, which can result in electrical shorts. In some examples, the openings in the damage pathways can allow for etchants used during the replacement gate process to reach the epitaxial material of the source/drain regions, which can disadvantageously damage the epitaxial material. In some embodiments, metal traces extending through the damage pathways can provide a bridge between the gate electrodes and the source/drain regions, which can result in electrical shorts. In some examples, the openings in the damage pathways can allow for etchants used during the replacement gate process to reach the epitaxial material of the source/drain regions, which can disadvantageously damage the epitaxial material.

In the embodiments described with reference to FIGS. 10A-11B, the first (upper) inner spacers 91C present at the top of the stack have the greatest width, as they are formed in the first (upper) recesses 88C that are formed in the first (upper) sacrificial materials 71C. The first (upper) recesses 88C have the greatest depth, as they are exposed to the greatest number of lateral etch steps. The greater the width of the inner spacers 91A, 91B, 91C, the greater the protection against damage pathways, and their negative effects. For example, the upper portion of the stacks may be the portion of the device most impacted by damage pathways. Therefore, the first (upper) inner spacers 91C formed in these recesses have the greatest width, and therefore the greatest protection against damage pathways, when compared to the inner spacers 91B, 91A formed in the lower portion of the stack.

However, as the width of the inner spacers 91A, 91B, 91C increases, the width of the gate electrode decreases. The narrower the gate electrode, the greater the electrical resistance of the gate electrode. Increased electrical resistance reduces device performance. The third (lower) inner spacers 91A have the least width, which provides a wider gate electrode portion having lesser resistance than the portions of the gate electrode adjacent to the wider first (upper spacers) inner 91C. The methods and structures described herein can adjust inner spacer width and gate electrode width to provide protection against damage pathways in the upper portions of the stacks, and minimizing gate electrode resistance in the lower portions of the stacks.

In FIGS. 12A-12D, epitaxial source/drain regions 192 are formed in the first recesses 86. In some embodiments, the source/drain regions 192 may exert stress on the nanostructures 55 in the n-type region 50N and/or the p-type region 50P, thereby improving performance. As illustrated in FIG. 12A, the epitaxial source/drain regions 192 are formed in the first recesses 86 such that each dummy gate 76 is disposed between respective neighboring pairs of the epitaxial source/drain regions 192. In some embodiments, the first spacers 81 are used to separate the epitaxial source/drain regions 192 from the dummy gates 76 and the inner spacers 91 are used to separate the epitaxial source/drain regions 192 from the sacrificial material 71 by an appropriate lateral distance so that the epitaxial source/drain regions 192 do not short out with subsequently formed gates of the resulting nano-FETs.

The epitaxial source/drain regions 192 in the n-type region 50N, e.g., the NMOS region, may be formed by masking the p-type region 50P, e.g., the PMOS region. Then, the epitaxial source/drain regions 192 are epitaxially grown in the first recesses 86 in the n-type region 50N. The epitaxial source/drain regions 192 may include any acceptable material appropriate for n-type nano-FETs. For example, if the nanostructures 55 are silicon, the epitaxial source/drain regions 192 may include materials exerting a tensile strain on the nanostructures 55, such as silicon, silicon carbide, phosphorous doped silicon carbide, silicon phosphide, or the like. The epitaxial source/drain regions 192 may have surfaces raised from respective upper surfaces of the nanostructures 55 and may have facets.

The epitaxial source/drain regions 192 in the p-type region 50P, e.g., the PMOS region, may be formed by masking the n-type region 50N, e.g., the NMOS region. Then, the epitaxial source/drain regions 192 are epitaxially grown in the first recesses 86 in the p-type region 50P. The epitaxial source/drain regions 192 may include any acceptable material appropriate for p-type nano-FETs. For example, if the nanostructures 55 are silicon germanium, the epitaxial source/drain regions 192 may comprise materials exerting a compressive strain on the nanostructures 55, such as silicon-germanium, boron doped silicon-germanium, germanium, germanium tin, or the like. The epitaxial source/drain 192 may also have surfaces raised from respective surfaces of the multi-layer stack and may have facets.

The epitaxial source/drain regions 192, nanostructures 55, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 192 may be in situ doped during growth.

As a result of the epitaxy processes used to form the epitaxial source/drain regions 192 in the n-type region 50N and the p-type region 50P, upper surfaces of the epitaxial source/drain regions 192 have facets which expand laterally outward beyond sidewalls of the nanostructures 55. In some embodiments, these facets cause adjacent epitaxial source/drain regions 192 of a same nano-FET to merge as illustrated by FIG. 12C. In other embodiments, adjacent epitaxial source/drain regions 192 remain separated after the epitaxy process is completed as illustrated by FIG. 12D. In the embodiments illustrated in FIGS. 12A-12D, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI regions 68.

The epitaxial source/drain regions 192 may comprise one or more semiconductor material layers. For example, the epitaxial source/drain regions 192 may comprise a first semiconductor material layer 192A, a second semiconductor material layer 192B, and a third semiconductor material layer 192C. Any number of semiconductor material layers may be used for the epitaxial source/drain regions 192. Each of the first semiconductor material layer 192A, the second semiconductor material layer 192B, and the third semiconductor material layer 192C may be formed of different semiconductor materials and may be doped to different dopant concentrations. In some embodiments, the first semiconductor material layer 192A may have a dopant concentration less than the second semiconductor material layer 192B and greater than the third semiconductor material layer 192C. In embodiments in which the epitaxial source/drain regions 192 comprise three semiconductor material layers, the first semiconductor material layer 192A may be deposited, the second semiconductor material layer 192B may be deposited over the first semiconductor material layer 192A, and the third semiconductor material layer 192C may be deposited over the second semiconductor material layer 192B.

In FIGS. 13A-13C, a first interlayer dielectric (ILD) 96 is deposited over the structure illustrated in FIGS. 12A-12D. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 192, the masks 78, and the first spacers 81. The CESL 94 may comprise a dielectric material, such as, silicon nitride, silicon oxide, silicon oxynitride, or the like, having a different etch rate than the material of the overlying first ILD 96.

In FIGS. 14A-14B, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

In FIGS. 15A and 15B, the dummy gates 76, and the masks 78 if present, are removed in one or more etching steps, so that second recesses 98 are formed. Portions of the dummy gate dielectrics 70 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 192. During the removal, the dummy gate dielectrics 70 may be used as etch stop layers when the dummy gates 76 are etched. The dummy gate dielectrics 70 may then be removed after the removal of the dummy gates 76.

In FIGS. 16A and 16B, the sacrificial materials 71A, 71B, 71C are removed extending the second recesses 98. The sacrificial materials 71A, 71B, 71C may be removed by an isotropic etching process such as wet etching or the like using etchants which are selective to removing the sacrificial materials 71A, 71B, 71C, while the second nanostructures 54A, 54B, 54C remain relatively unetched as compared to the sacrificial materials 71A, 71B, 71C. In embodiments in which the sacrificial materials 71A, 71B, 71C include, e.g., silicon oxide (SiO₂), and the nanostructures 54A-54C include, e.g., Si or SiC, or the like may be used to remove the sacrificial materials 71A, 71B, 71C. The sacrificial material 71 may be completely removed, or a residue of the sacrificial material 71 may remain on sidewalls of the inner spacers in the second recesses 98 (see e.g., FIG. 17C).

In some embodiments, the STI regions 68 may be etched while removing the sacrificial material 71, but the total amount of loss in the STI regions 68 may be reduced by controlling etching parameters (e.g., timing) while removing the sacrificial material 71. In other embodiments, the STI regions 68 may include a hard mask (not separately illustrated) at a top surface to protect the underlying STI regions 68 from etching while patterning and removing the sacrificial material 71. In such embodiments, the hard mask may comprise, for example, a nitride.

In FIGS. 17A and 17B, gate dielectric layers 100 and gate electrodes 102 are formed for replacement gates. The gate dielectric layers 100 and the gate electrodes 102 provide functional gate structures. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54A, 54B, 4C. The gate dielectric layers 100 may also be deposited on top surfaces of the first ILD 96, the CESL 94, the first spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A and 17B, the gate electrodes 102 may comprise any number of liner layers, any number of work function tuning layers, and a fill material.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

Referring to FIG. 17B, the gate electrode 102 wraps around the nanostructures 55, e.g., second nanostructures 54A, 54B, 54C, and can be referred to as a gate all around (GAA) structure. The gate all around (GAA) structure has a pyramid geometry in the illustrated cross-section. The conductive material of the gate electrodes 102 and the dielectric material of the gate dielectric layers 100 fills the space that is created by removing the sacrificial materials 71A, 71B, 71C. In some embodiments, because the first (upper) inner spacers 91C have a greater width than the second (middle) inner spacers 91B, and the second (middle) inner spacers 91B have a greater width than the third (lower) inner spacers 91A; the space occupied by the conductive material of the gate electrode 102 increases from the upper portion of the nanostructure stack 55 to the base of the nanostructure stack 55. Filling these spaces with the conductive material for the gate electrode 102 produces a gate electrode 102 having a pyramid geometry, in which pyramid geometry includes a first width at a top surface of a gate structure within the nanostructure stack 55 that is less than a second width at a base of the gate structure within the nanostructure stack 55.

It is noted that the geometry for the portions of the gate electrode 102 within the stack of nanostructures 55 depicted in FIG. 17B is only one example of a gate structure that can be provided by the methods described herein.

FIG. 17C illustrates a detailed view of various elements of FIG. 17B, including the epitaxial source/drain regions 192, the gate dielectric layers 100, the gate electrodes 102, the second nanostructures 54, and the inner spacers 91. In some embodiments, illustrated by FIG. 17C, a residue of the sacrificial material 71 may remain on the inner spacers 91, such as between the inner spacers 91 and the gate dielectric layers 100/gate electrodes 102. For example, the sacrificial material 71 may not be fully removed, and the gate dielectric layers 100 may be formed on the remaining sacrificial material 71. Because the sacrificial material 71 is an insulating material (e.g., silicon oxide), the remaining residue may not significantly impact the electrical performance of the resulting device. FIG. 17C only depicts one of the inner spacers 91 depicted in FIG. 17B. However, the inner spacer 91 illustrated in FIG. 17C may be representative of each of the inner spacers 91A, 91B, 91C that are depicted in FIG. 17B.

FIGS. 21A-21C illustrate some examples of how the width of the inner spacers 91A, 91B, 91C can be adjusted to provide for different gate length portions of the gate electrode 102 within a stack of nanostructures 55. The width of a portion of the gate electrode 102 between the opposing inner spacers 91A, 91B, 91C is a gate length portion. The inner spacers are not depicted in FIGS. 21A-21C, but can be observed by review of FIG. 17B.

FIG. 21A illustrates the embodiment described above with reference to FIG. 17B. The upper portion 102C of the gate electrode 102 is present between the first (upper) inner spacers 91C. The first (upper) inner spacers 91C have the greatest width. Therefore, the upper portion 102C of the gate electrode 102 has the narrowest gate length. The lower portion 102A of the gate electrode is present between the third (lower) inner spacers 91A. The third (lower) inner spacers 91A have the narrowest width. Therefore, the lower portion 102A of the gate electrode 102 has the widest gate length. The middle portion 102B of the gate electrode 102 has a gate length between the upper portion 102C and the lower portion 102A. This is a pyramid geometry with a gradual change in the width of the pyramid, e.g., a gradual change in the gate length. This is provided by separately etching each disposable layer at least once in the process sequence used to form the inner spacers 91A, 91B, and 91C.

However, FIGS. 21B and 21C illustrate that a gate electrode 102 can be formed having adjacently stacked layers for the gate electrode material within the stack of nanostructures 55 having the same gate length. This can be provided by recessing the sidewall spacer to expose at least two sidewalls of the disposable spacer to be etched simultaneously with the same etch process. FIG. 21B illustrates that the two lower nanostructures for the lower portion 102A and the middle portion 102B of the gate electrode have the same gate length, which is greater than the gate length in the upper portion 102C. FIG. 22C illustrates that the two upper nanostructures for the middle portion 102B and the upper portion 102A for the gate electrode have the same gate length that is less than the gate length for the lower portion 102A.

In FIGS. 18A-18C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the contacts 114, discussed below with respect to FIGS. 21A-21C) penetrate through the gate mask 104 to contact the top surface of the recessed gate electrodes 102.

As further illustrated by FIGS. 18A-18C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

In FIGS. 19A-19C, the second ILD 106, the first ILD 96, the CESL 94, and the gate masks 104 are etched to form third recesses 108 exposing surfaces of the epitaxial source/drain regions 192 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 192 and/or the gate structure, and a bottom of the third recesses 108 may be level with (e.g., at a same level, or having a same distance from the substrate), or lower than (e.g., closer to the substrate) the epitaxial source/drain regions 192 and/or the gate structure. Although FIG. 19B illustrate the third recesses 108 as exposing the epitaxial source/drain regions 192 and the gate structure in a same cross section, in various embodiments, the epitaxial source/drain regions 192 and the gate structure may be exposed in different cross-sections, thereby reducing the risk of shorting subsequently formed contacts. After the third recesses 108 are formed, silicide regions 110 are formed over the epitaxial source/drain regions 192. In some embodiments, the silicide regions 110 are formed by first depositing a metal (not shown) capable of reacting with the semiconductor materials of the underlying epitaxial source/drain regions 192 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 192, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 20A-C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material 118, and is electrically coupled to the underlying conductive feature (e.g., gate electrode 102 and/or silicide region 110 in the illustrated embodiment). The contacts 114 are electrically coupled to the gate electrode 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material 118 may be copper, a copper alloy, silver, gold, tungsten, cobalt, aluminum, nickel, or the like. A planarization process, such as a CMP, may be performed to remove excess material from a surface of the second ILD 106.

Embodiments may achieve advantages. For example, the methods and structure provides a multi disposable layer in the stack used for forming nanostructure channels, which when combined with selective etching can create a tunable inner spacer profile. Selective etching can control a profile of the disposable layers, layer by layer. In some embodiments, a tunable inner spacer profile can both enlarge the metal gate process extrusion and provide a reduction in capacitance.

In an embodiment, a semiconductor device includes a source/drain region, a first nanostructure adjacent the source/drain region, a second nanostructure adjacent the source/drain region, the second nanostructure disposed above the first nanostructure, a third nanostructure adjacent the source/drain region, the second nanostructure disposed above the second nanostructure, and a gate structure around the first nanostructure, the second nanostructure, and the third nanostructure, a first portion of the gate structure disposed between the first nanostructure and the second nanostructure, a second portion of the gate structure disposed between the second nanostructure and the third nanostructure, the second portion of the gate structure having a smaller length than the first portion of the gate structure. In an embodiment, the semiconductor device of also includes a first inner spacer between the source/drain region and the first portion of the gate structure, and a second inner spacer between the source/drain region and the second portion of the gate structure. In one embodiment, the second inner spacer has a greater width than the first inner spacer. In one embodiment, the first inner spacer and the second inner spacer comprise a same dielectric material. In one embodiment, the gate structure includes a gate dielectric; and a metal gate electrode on the gate dielectric. In one embodiment, the semiconductor device includes a fin, a third portion of the gate structure disposed between the first nanostructure and the fin, the third portion of the gate structure having a greater length than the second portion of the gate structure.

In another embodiment, a semiconductor device including a source/drain region, a nanostructure adjacent the source/drain region, a gate structure around the nanostructure, a first inner spacer between the gate structure and the source/drain region, the first inner spacer having a first width, and a second inner spacer 91C between the gate structure 100, 102 and the source/drain region, the second inner spacer having a second width, the second width being greater than the first width, the first inner spacer and the second inner spacer disposed at opposing sides of the nanostructure. In an embodiment, the gate structure comprises a metal gate electrode. In an embodiment, the metal gate electrode has a pyramid geometry. In an embodiment, the gate structure further includes a conformal gate dielectric layer. In an embodiment, the first inner spacer and the second inner spacer include a same dielectric material. In an embodiment, the gate structure has a first gate length adjacent the first inner spacer, and a second gate length adjacent the second inner spacer, wherein the first gate length is greater than the second gate length.

In another embodiment, a method of forming a semiconductor device is provided that includes forming a stack of at least a first set of semiconductor layers and a second set of semiconductor layers, replacing the first set of semiconductor layers with disposable layers, forming a sidewall spacer along a sidewall of the stack, wherein at least a first portion of the disposable layers is exposed by the sidewall spacer, first laterally etching the first portion of the disposable layers that are exposed, recessing the sidewall spacer to expose a second portion of the disposable layers, second laterally etching the second portion of the disposable layer that are exposed by the sidewall spacer, forming inner spacers in recesses formed by the first laterally etching and the second laterally etching of the disposable layers, and replacing remaining portions of the disposable layers with a gate structure 100, 102, the gate structure disposed on the second set of semiconductor layers. In an embodiment, the sidewall spacer along the sidewall of the stack is removed before forming the gate structure. In an embodiment, the first set of semiconductor layers has a different composition than the second set of semiconductor layers. In an embodiment, the gate electrode of the gate structure has a pyramid geometry. In an embodiment, a gate electrode of the gate structure has a narrower width at a second surface of the stack than a first surface of the stack, the second surface opposite the first surface. In an embodiment, forming the inner spacers comprises performing a conformal deposition of a dielectric material followed by an etch process. In an embodiment, the recessing of the sidewall spacer includes performing an anisotropic etch process that selectively etches a material of the sidewall spacer at a faster rate than a material of the disposable layers. In an embodiment, the method further includes source/drain regions on opposing sides of the stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a source/drain region;
a first nanostructure adjacent the source/drain region;
a second nanostructure adjacent the source/drain region, the second nanostructure disposed above the first nanostructure;
a third nanostructure adjacent the source/drain region, the second nanostructure disposed above the second nanostructure; and
a gate structure around the first nanostructure, the second nanostructure, and the third nanostructure, a first portion of the gate structure disposed between the first nanostructure and the second nanostructure, a second portion of the gate structure disposed between the second nanostructure and the third nanostructure, the second portion of the gate structure having a smaller length than the first portion of the gate structure.

2. The semiconductor device of claim 1, further comprising:
a first inner spacer between the source/drain region and the first portion of the gate structure; and
a second inner spacer between the source/drain region and the second portion of the gate structure.

3. The semiconductor device of claim 2, wherein the second inner spacer has a greater width than the first inner spacer.

4. The semiconductor device of claim 2, wherein the first inner spacer and the second inner spacer comprise a same dielectric material.

5. The semiconductor device of claim 1, wherein the gate structure comprises:
a gate dielectric; and
a metal gate electrode on the gate dielectric.

6. The semiconductor device of claim 1, further comprising:
a fin, a third portion of the gate structure disposed between the first nanostructure and the fin, the third portion of the gate structure having a greater length than the second portion of the gate structure.

7. A semiconductor device comprising:
a source/drain region;
a nanostructure adjacent the source/drain region;
a gate structure around the nanostructure;
a first inner spacer between the gate structure and the source/drain region, the first inner spacer having a first width; and
a second inner spacer between the gate structure and the source/drain region, the second inner spacer having a second width, the second width being greater than the first width, the first inner spacer and the second inner spacer disposed at opposing sides of the nanostructure.

8. The semiconductor device of claim 7, wherein the gate structure comprises a metal gate electrode.

9. The semiconductor device of claim 8, wherein the metal gate electrode has a pyramid geometry.

10. The semiconductor device of claim 8, wherein the gate structure further comprises a conformal gate dielectric layer.

11. The semiconductor device of claim 8, wherein the first inner spacer and the second inner spacer comprise a same dielectric material.

12. The semiconductor device of claim 8, wherein the gate structure has a first gate length adjacent the first inner spacer, and a second gate length adjacent the second inner spacer, wherein the first gate length is greater than the second gate length.

13. A method of forming a semiconductor device comprising:
forming a stack of at least a first set of semiconductor layers and a second set of semiconductor layers;
replacing the first set of semiconductor layers with disposable layers;
forming a sidewall spacer along a sidewall of the stack, wherein at least a first portion of the disposable layers is exposed by the sidewall spacer;
first laterally etching the first portion of the disposable layers that are exposed;
recessing the sidewall spacer to expose a second portion of the disposable layers;
second laterally etching the second portion of the disposable layers that are exposed by the sidewall spacer;
forming inner spacers in recesses formed by the first laterally etching and the second laterally etching of the disposable layers; and
replacing remaining portions of the disposable layers with a gate structure, the gate structure disposed on the second set of semiconductor layers.

14. The method of claim 13, wherein the sidewall spacer along the sidewall of the stack is removed before forming the gate structure.

15. The method of claim 13, wherein the first set of semiconductor layers has a different composition than the second set of semiconductor layers.

16. The method of claim 13, wherein a gate electrode of the gate structure has a pyramid geometry.

17. The method of claim 13, wherein a gate electrode of the gate structure has a narrower width at a second surface of the stack than a first surface of the stack, the second surface opposite the first surface.

18. The method of claim 13, wherein forming the inner spacers comprises performing a conformal deposition of a dielectric material followed by an etch process.

19. The method of claim 13, wherein the recessing of the sidewall spacer comprises performing an anisotropic etch process that selectively etches a material of the sidewall spacer at a faster rate than a material of the disposable layers.

20. The method of claim 13, further comprising forming source/drain regions on opposing sides of the stack.
